(19) United States
(12) Patent Application Publication
(10) Pub. No.: US 2024/0369948 A1
(43) Pub. Date: Nov. 7, 2024

(54) THERMAL CONDITIONING UNIT, SUBSTRATE HANDLING DEVICE AND LITHOGRAPHIC APPARATUS

(71) Applicant: ASML NETHERLANDS B.V., Veldhoven (NL)

(72) Inventor: Gijs KRAMER, Nijmegen (NL)

(73) Assignee: ASML NETHERLANDS B.V., Veldhoven (NL)

(21) Appl. No.: 18/687,727

(22) PCT Filed: Aug. 8, 2022
(86) PCT No.: PCT/EP2022/072267

§ 371 Date: Feb. 28, 2024

(30) Foreign Application Priority Data
Sep. 16, 2021 (EP) 21197020.7

(51) Int. Cl. G03F 7/00

(52) U.S. Cl. CPC G03F 7/70875; G03F 7/70525; G03F 7/707; G03F 7/70783

(57) ABSTRACT

A thermal conditioning unit to thermally condition a substrate, the thermal conditioning unit including: a top surface; a plurality of gas inlets and gas outlets provided in the top surface; a plurality of pressure valves connected to the plurality of gas inlets and gas outlets, wherein each of the plurality of pressure valves is configured to, during use, be connected to a pressure supply to generate a spatial pressure distribution across the top surface of the thermal conditioning unit; and a control device configured to control the plurality of pressure valves to generate, during use, the spatial pressure distribution, wherein the control device is configured to receive substrate shape data representing a shape of the substrate to be conditioned, and wherein the control device is configured to control the plurality of pressure valves to adapt the spatial pressure distribution based on the substrate shape data.

### CROSS-REFERENCE TO RELATED APPLICATION

The application claims priority of EP application Ser. No. 21/197,020.7 which was filed on 16 Sep. 2021 and which is incorporated herein in its entirety by reference.

### FIELD

The present invention relates to a temperature conditioning unit for use in a substrate handling device, a substrate support or a lithographic apparatus, and a method of using the temperature conditioning unit.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate, a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

In order to ensure an accurate positioning of the pattern on the substrate, it is important to ensure that the substrate temperature or temperature distribution is accurately known and within predetermined boundaries. In order to ensure this, a substrate is typically thermally conditioned prior to the application of the pattern onto the substrate. It has been observed that substrates as currently applied to semiconductor devices may not be conditioned properly, using known conditioning systems.

### SUMMARY

It is an objective of the present invention to enable an improved thermal conditioning of substrates, in particular, substrates that are applied in a lithographic apparatus.

According to an aspect of the invention, there is provided a thermal conditioning unit to thermally condition a substrate comprising:
a top surface;
a plurality of gas inlets and gas outlets provided in the top surface;
a plurality of pressure valves connected to the plurality of gas inlets and gas outlets, wherein each of the plurality of pressure valves is configured to, during use, be connected to a pressure supply to generate a spatial pressure distribution across the top surface of the thermal conditioning unit,
a control device configured to control the plurality of pressure valves to generate, during use, the spatial pressure distribution,
wherein the control device is configured to receive substrate shape data representing a shape of the substrate to be conditioned, and wherein the control device is configured to control the plurality of pressure valves to adapt the spatial pressure distribution based on the substrate shape data.

According to an aspect of the invention, there is provided a method of using a thermal conditioning unit according to the invention.

According to another aspect of the invention, there is provided a substrate handling device comprising a thermal conditioning unit according to the invention.

According to another aspect of the invention, there is provided a substrate support comprising a thermal conditioning unit according to the invention.

According to another aspect of the invention, there is provided a method of using a substrate support according to the invention.

According to another aspect of the invention, there is provided a lithographic apparatus comprising a thermal conditioning unit, a substrate handling device or a substrate support according to the invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a detailed view of a part of the lithographic apparatus of FIG. 1;

FIG. 3 schematically depicts a position control system;

FIG. 4 schematically depicts a thermal conditioning unit according to an embodiment of the present invention;

FIG. 5 schematically depicts another thermal conditioning unit according to an embodiment of the present invention;

FIGS. 6(a)-6(c) schematically depict spatial pressure distributions which can be provided by a thermal conditioning unit according to the invention, in order to condition warped substrates;

FIG. 7 schematically depicts a substrate handling device according to the present invention.

FIG. 8 schematically depicts another thermal conditioning unit according to an embodiment of the invention.

FIG. 9 schematically depicts another thermal conditioning unit according to an embodiment of the invention.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

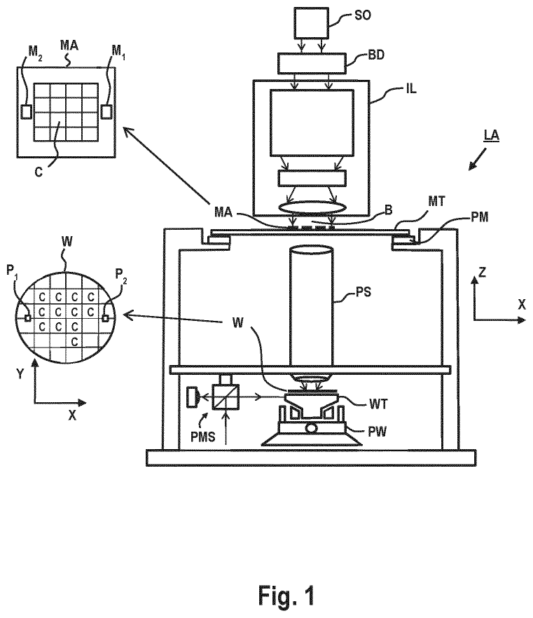

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

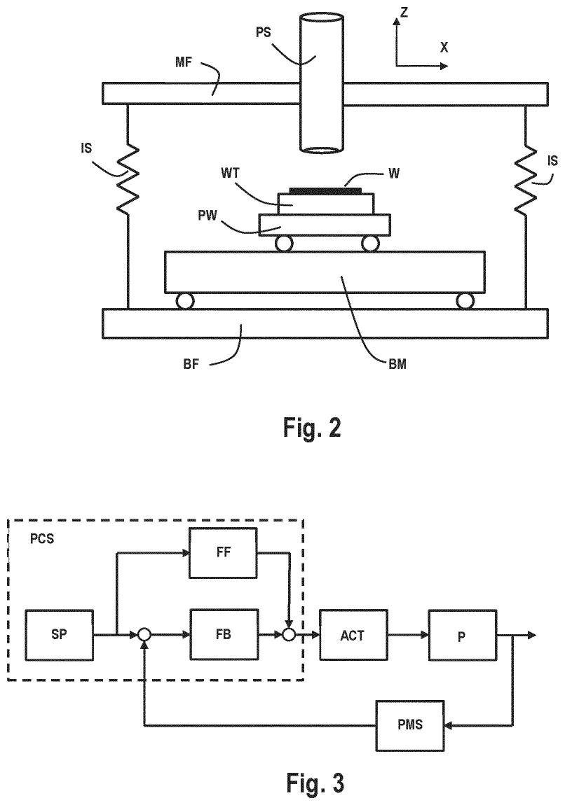

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor, a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads are arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the second positioner PW is able to move the substrate support WT relative to the projection system PS with a high accuracy over a large range of movement.

The first positioner PM and the second positioner PW each are provided with an actuator to move respectively the mask support MT and the substrate support WT. The actuator may be a linear actuator to provide a driving force along a single axis, for example the y-axis. Multiple linear actuators may be applied to provide driving forces along multiple axis. The actuator may be a planar actuator to provide a driving force along multiple axis. For example, the planar actuator may be arranged to move the substrate support WT in 6 degrees of freedom. The actuator may be an electromagnetic actuator comprising at least one coil and at least one magnet. The actuator is arranged to move the at least one coil relative to the at least one magnet by applying an electrical current to the at least one coil. The actuator may be a moving-magnet type actuator, which has the at least one magnet coupled to the substrate support WT respectively to the mask support MT. The actuator may be a moving-coil type actuator which has the at least one coil coupled to the substrate support WT respectively to the mask support MT. The actuator may be a voice-coil actuator, a reluctance actuator, a Lorentz-actuator or a piezo-actuator, or any other suitable actuator.

The lithographic apparatus LA comprises a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW. The actuator ACT drives the plant P, which may comprise the substrate support WT or the mask support MT. An output of the plant P is a position quantity such as position or velocity or acceleration. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies.

Prior to the patterning of a substrate by the patterned radiation beam, i.e. the radiation beam endowed with a pattern of the patterning device, the substrate is loaded in to the lithographic apparatus and conditioned so as to be in a suitable state to be patterned. Such loading and conditioning can e.g. be performed by a substrate handling device, which can e.g. be part of the lithographic apparatus.

Such conditioning typically involves a thermal conditioning to arrive at a substrate having a desired, substantially uniform, temperature or temperature distribution. In order to arrive at such a desired temperature or temperature distribution, a substrate can be conditioned using a temperature conditioning unit.

In a known arrangement, such a thermal conditioning unit is configured to receive a substrate and suspend the substrate by means of a vacuum preloaded gas bearing. The substrate is maintained in said state and the temperature is conditioned, by means of the applied gas of the gas bearing.

In order to ensure an accurate temperature conditioning, it may be desirable that the substrate is suspended by the vacuum preloaded gas bearing at a desired fly height. This is particularly desirable where the substrate presents a large contact surface area, and/or where the substrate undergoes relative movement due to e.g. processes such as pre-alignment. It may be further desirable that, during the loading and unloading of the substrate to and from the thermal conditioning unit, and during the thermal conditioning process, the substrate does not come in contact with the conditioning unit in order to avoid damage to the substrate or the generation of debris. Where the substrate has a well-defined and sufficiently small contact area and/or there is no relative movement of the substrate, the substrate may contact the thermal conditioning unit without substantial risk of damage, particle or debris generation. A sufficiently small contact area in this context does not only relate to a contact area fraction of the total substrate surface area, but also to the size of the individual contacting features. The sufficiently small contact area is sized so as to induce only an acceptably small risk of particulate/debris capture between the substrate and contacting features. Particles and debris can otherwise lead to contamination, damage or undesirable substrate unflatness. An exemplary sufficiently small contact area may be on the order of around 1.5% of the full substrate surface area, with individual features of e.g. around 0.5 mm. It will be appreciated that other contact areas and feature sizes may be used providing the risk of particulate/debris capture and related contamination and damage remains acceptably small.

It has been observed by the inventor that these requirements may be difficult to be met at present, in particular when deformed or warped substrates are to be conditioned. It has been observed that when such a deformed or warped substrate is loaded onto a known thermal conditioning unit, damage, e.g. scratches, can be caused to the substrate. It has also been observed that it may not be possible to maintain a deformed or warped substrate at the desired fly height using a known thermal conditioning unit.

In accordance with an aspect of the present invention, there is provided an improved thermal conditioning unit for substrates, the improved thermal conditioning unit being capable of alleviating or at least mitigating the aforementioned issues.

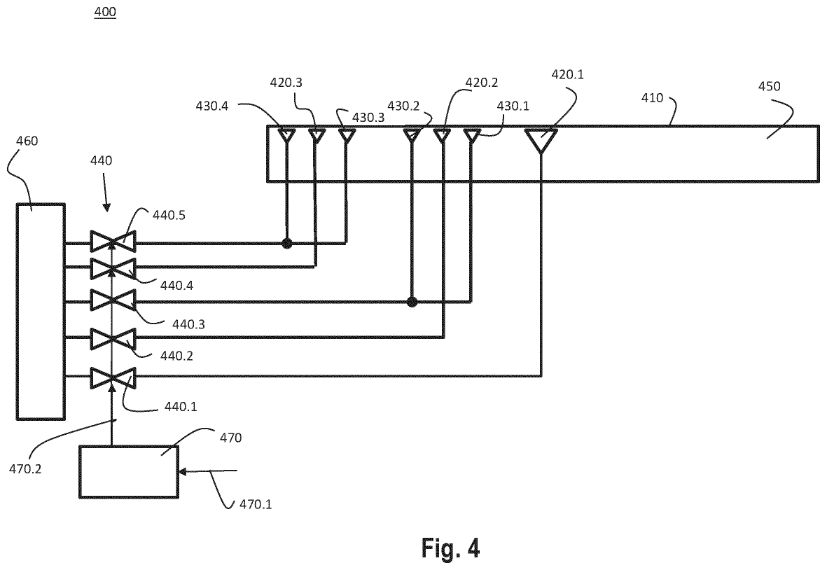

FIG. 4 schematically shows a thermal conditioning unit 400 according to an embodiment of the present invention.

In the embodiment as shown, the thermal conditioning unit 400 according to the invention comprises a top surface 410 and a plurality of gas inlets 420.1, 420.2, 420.3 and gas outlets 430.1, 430.2, 430.3, 430.4 provided in the top surface 410. In accordance with the invention, the thermal conditioning unit 400 further comprises a plurality of pressure valves 440 connected to the plurality of gas inlets 420 and gas outlets 430. In the embodiment as shown, gas inlet 420.1 is connected to pressure valve 440.1, whereas gas outlets 430.1 and 430.2 are connected to pressure valve 440.3. Gas inlet 420.2 is connected to pressure valve 440.2. Gas outlets 430.3 and 430.4 are connected to pressure valve 440.5 and gas inlet 420.3 is connected to pressure valve 440.4. The thermal conditioning unit 400 may e.g. comprise a disk-shaped structure 450 provided with suitable channels arranged between the gas inlets 420 and gas outlets 430 and an exterior surface of the structure 450 onto which hoses or ducts can be connected, as will be shown in detail below.

Note that, within the meaning of the present invention, gas may e.g. refer to air or conditioned air such as CDA or XCDA. Gas may also refer to any other suitable gas to achieve the thermal conditioning of the substrate.

In accordance with the present invention, the plurality of pressure valves 440 are configured to, during use, be connected to a pressure supply 460 to generate a spatial pressure distribution across the top surface 410 for supporting the substrate. In other words pressure valves 440 are configured to distribute pressure in order to support the substrate. Such a spatial pressure distribution may provide a support to the substrate by means of a combination of repelling forces, generated by gas exhausted from the gas outlets 430, and attractive forces, generated by gas evacuated via the gas inlets 420. Within the meaning of the present invention, the process of arranging a substrate near the top surface 410 of the conditioning unit such that it is held in a supported manner above the top surface by means of the spatial pressure distribution is also referred to as a clamping process. Note however that the substrate by means of the spatial pressure distribution remains suspended above the top surface in the clamped state. In an embodiment, the spatial pressure distribution thus provides a vacuum preloaded gas bearing for the substrate. Note that, within the meaning of the present invention, the use of vacuum is not limited to extremely low pressures. Vacuum or low pressure is, within the meaning of the present invention, used to denote a pressure that is lower than an ambient pressure. As such, in an embodiment, the pressure supply 460 may e.g. comprise a high pressure source, e.g. 1-10 bar overpressure, or e.g. approximately 1.5 bar overpressure, which can be connected to the gas outlets 430.1-430.4 and a low pressure source, e.g. at a low pressure of −0.2 bar, which can be connected to the gas inlets 420.1-420.3. A tuning range of the high pressure source may e.g. be approx. +/−0.5 bar, a tuning range of the low pressure source may e.g. be approx. +/−0.1 bar. It can also be pointed out that at some point during the clamping process of the substrate, the pressure at one or more of the gas outlets or inlets can be set to zero, i.e. ambient pressure. In other words, pressure valves 440 can be pressure-controlled or open to ambient pressure. In use therefore, each pressure valve 440.1, 440.2, 440.3, 440.4, 440.5 may be supplied, at any given time, with one of an over-pressure, under-pressure, or ambient pressure, so as to generate the spatial pressure distribution. In other words, the pressure valves 440 may be supplied, in use, with an over-pressure, under-pressure, and/or ambient pressure. Advantageously, enabling pressure valves 440 to switch between ambient pressure and over- and/or under-pressure improves the clamping capabilities of the invention with respect to warped substrates.

In accordance with the present invention, the thermal conditioning unit 400 further comprises a control device 470 that is configured to receive substrate shape data, e.g. by means of an input signal 470.1, the substrate shape data representing a shape of the substrate to be conditioned and is configured to control the plurality of pressure valves, based on the substrate shape data. By doing so, the control device 470 can control the spatial pressure distribution generated by the gas inlets and gas outlets, and as a result, control the manner in which the particular substrate having the particular shape, is suspended or held above the top surface 410 of the thermal conditioning unit 400. As such, the applied or generated spatial pressure distribution can be tailored to take account of the shape of the substrate that is to be conditioned.

As an example, the substrate shape data can comprise warpage data of the substrate. Warpage data in general refer to data indicative of out-of-plane deformations of a substrate. Due to the various processes applied to semiconductor substrates, their shape may deviate from a substantially flat disc. Examples of such deviating shape can e.g. be umbrella-shaped substrates, or bowl-shaped substrates, or saddle-shaped substrates. By controlling the applied spatial pressure distribution in accordance with the present invention, one can ensure that, during the thermal conditioning of the warped or deformed substrate, the warpage or deformation is, at least partially, reduced. As a result, the fly-height of the substrate that needs to be conditioned will be more uniform, resulting in an improved thermal conditioning. In some embodiments, for example of a substrate support table comprising the thermal conditioning unit of the invention, as an alternative to or in addition to improved thermal conditioning, substrate clamping may be improved due to reduced warpage or deformation or the substrate to be clamped prior to measurement or exposure.

In a method of using the thermal conditioning unit 400 according to the invention therefore, the pressure valves 440 are connected to a pressure supply 460, and the control device 470 receives shape data representing the shape of the substrate to be conditioned or clamped, and the supply of an over-pressure, under-pressure and/or ambient pressure to each of the pressure valves 440 is controlled so as to generate the spatial pressure distribution across the top surface 410 of the thermal conditioning unit 400, wherein the spatial pressure distribution is based on the substrate shape data. Such a method may also be used for a substrate support comprising the thermal conditioning unit according to the invention.

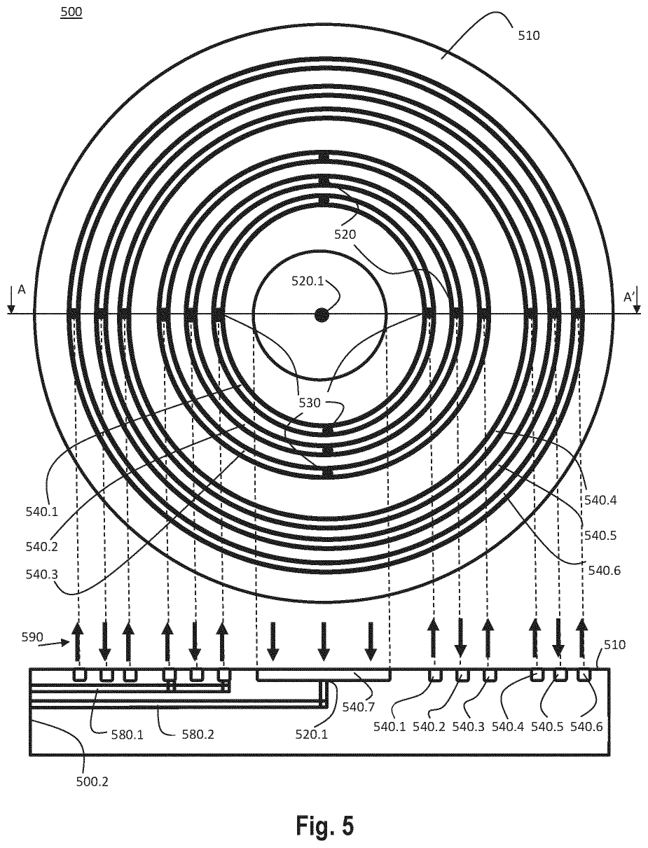

FIG. 5 schematically shows in more detail an embodiment of a thermal conditioning unit 500 according to the present invention. The top portion of FIG. 5 schematically shows a top view of the thermal conditioning unit 500, the top portion having a top surface 510. In the embodiment as shown, the thermal conditioning unit 500 comprises a plurality of gas inlets 520 and gas outlets 530. In the embodiment as shown, the gas inlets and gas outlets are grouped along a plurality of concentric circles. In particular, the top surface of the thermal conditioning unit 500 comprises a plurality of concentrically arranged circular grooves 540.1-540.6, whereby each groove is associated with one or more gas inlets 520 or one or more gas outlets 530. In the embodiment as shown, each of the grooves 540.1, 540.3 comprises 4 gas outlets 530, whereas groove 540.2 comprises 4 gas inlets 520. As will be appreciated by the skilled person, the number of inlets or outlets associated with a particular groove may vary, e.g. depending on the radius of the groove. In an embodiment, a minimal distance between adjacent inlets or outlets associated with a particular groove can be considered. Note that not all gas inlets and gas outlets associated with grooves 540.4-540.6 are shown. As will be understood by the skilled person, the gas inlets or gas outlets associated with a particular groove may be fluidly connected to each other by means of suitable channels inside the thermal conditioning unit 500. By doing so, the gas inlets or gas outlets associated with a particular groove can be connected to a single pressure source or pressure supply. It can however be pointed out that, in general, the gas inlets or gas outlets arranged along a particular circle of the plurality of concentric circles or associated with a particular groove need not be fluidly connected. In general, each gas inlet or gas outlet could be connected to its own dedicated pressure supply. In such an arrangement, one can realize additional or more detailed pressure variations across the top surface 510. In particular, by doing so, one can realise an angularly varying pressure distribution, in addition to a radially varying pressure distribution.

With respect to the embodiment as shown in FIG. 5, i.e. whereby the gas inlets and gas outlets are grouped along a plurality of concentric circles, it can be pointed out that this is merely an example layout of the gas inlets and outlets. It will be appreciated that other layouts can be considered as well. The following examples are worth mentioning:
A honeycomb type of layout;
A spiral configuration whereby the gas inlets and/or gas outlets are arranged along one or more spiral shaped trajectories.
A configuration whereby the top surface is segmented into a plurality of bearing areas or islands, each area or island e.g. having 3 gas outlets and 1 gas outlet. Such a plurality of bearing areas or islands can be arranged in concentric ring patterns.
Polygon shaped patterns, e.g. regular polygonal shaped patterns or diamond shaped patterns can be considered as a basis to distribute the gas inlets and outlets.
Other regular patterns of gas inlets and gas outlets having a rotational symmetry or a two-fold mirror symmetry in the XY-plane, the XY-plane in general referring to the plane of the substrate.

The bottom portion of FIG. 5 schematically shows a cross-sectional view of the thermal conditioning unit 500 along line A-A′. In the cross-sectional view, the grooves 540.1-540.6 are schematically shown, as well as a central recess 540.7 associated with gas inlet 520.1. The cross-sectional view of the thermal conditioning unit 500 further schematically shows a few internal ducts or channels 580.1, 580.2 connecting the gas inlets and gas outlets to a side surface 500.2 of the thermal conditioning unit 500. In the embodiment as shown, duct or channel 580.1 connects the gas outlets associated with grooves 540.3 and 540.1 to the side surface 500.2, whereas duct or channel 580.2 connects the gas inlet 520.1 to the side surface 500.2. In the arrangement as shown, the gas outlets associated with grooves 540.3 and 540.1 will thus be supplied with gas from a common gas supply. Note that in general, the gas supply to the outlets associated with grooves 540.3 and 540.1 may be from different gas supplies. In an embodiment, the side surface 500.2 can be provided with connectors to connect the ducts or channels 580.1, 580.2 to a pressure supply for supplying or extracting gas from the gas inlets and gas outlets. During use, when gas is supplied to the gas outlets 530 and gas is extracted via gas inlets 520, 520.1, attractive and repelling forces can be generated on a substrate that is facing the top surface 510 of the thermal conditioning unit 500. In FIG. 5, the arrows 590 schematically indicate the direction of the repelling and attractive forces as generated using the gas inlets and gas outlets.

In an embodiment, the spatial pressure distribution as generated can be considered to act as a vacuum preloaded gas bearing which supports the substrate. By suitable control of the applied high and low pressures, the fly-height, i.e. the distance between the substrate and the top surface of the thermal conditioning unit, can be controlled to a desired value.

In the embodiment as shown in FIG. 5, the spatial pressure distribution as generated by controlling the gas supplied to the gas outlets and the gas extracted from the gas inlets can be considered to comprises a plurality of ring-shaped areas or pressure areas that are concentrically arranged. This is due to the particular arrangement of the gas inlets along a plurality of concentric circles and the arrangement of the gas outlets along a plurality of concentric circles.

In the embodiment as shown in FIG. 5, the top surface 510 of the thermal conditioning unit 500 comprises a plurality of concentrically arranged ring-shaped grooves, each groove comprising a plurality of gas inlets or gas outlets. Alternatively, instead of ring-shaped grooves, the grooves may be arc-shaped, each groove e.g. being shaped as a segment of a circle.

With respect to the spatial pressure distribution as generated by the thermal conditioning unit according to the present invention, the following can further be mentioned: the purpose of the spatial pressure distribution as generated using the available gas inlets and gas outlets is to allow or enable an accurate positioning of the substrate that is to be conditioned above the top surface of the thermal conditioning unit. In the example shown in FIG. 5, such a spatial pressure distribution is realised by a particular arrangement of inlets and outlets along a plurality of concentric circles. In the arrangement as shown, groove 540.5, serving as gas inlet is enclosed by grooves 540.4 and 540.6, both serving as gas outlets. In a similar manner, groove 540.2, serving as gas inlet is enclosed by grooves 540.1 and 540.3, both serving as gas outlets. It will be appreciated by the skilled person that alternative arrangements of gas inlets and gas outlets can be considered as well. As an example, an arrangement whereby gas inlets and gas outlets are alternatingly arranged in a radial direction, can be considered as well. It can further be mentioned that the radial distance between adjacent grooves need not be the same for all grooves or circles onto which the inlets and outlets are applied.

In accordance with the present invention, the thermal conditioning unit further comprises a control device configured to control the plurality of pressure valves to generate, during use, the spatial pressure distribution. In particular, in accordance with the present invention, the control device is configured to receive substrate shape data representing shape data of the substrate to be conditioned, and wherein the control device is configured to control the plurality pressure valves to adapt the spatial pressure distribution based on the substrate shape data. By adapting the spatial pressure distribution based on the substrate shape data, a deformation or warpage of the substrate that is to be conditioned can be taken into account. Referring to the bottom portion of FIG. 5, the control unit or control device of the thermal conditioning unit 500 may be configured to control the amplitude of particular parts of the spatial pressure distribution as generated. In this respect, it can be noted that the arrows 590 shown in FIG. 5 can be considered a representation of the spatial pressure distribution as generated. It can be pointed out that the spatial pressure distribution as applied should not be considered a static distribution that is applied instantaneously. Rather, at least during the clamping process, i.e. the process during which a substrate is brought into a clamped state by means of the spatial pressure distribution, the pressures as applied at the various gas inlets and gas outlets may vary over time.

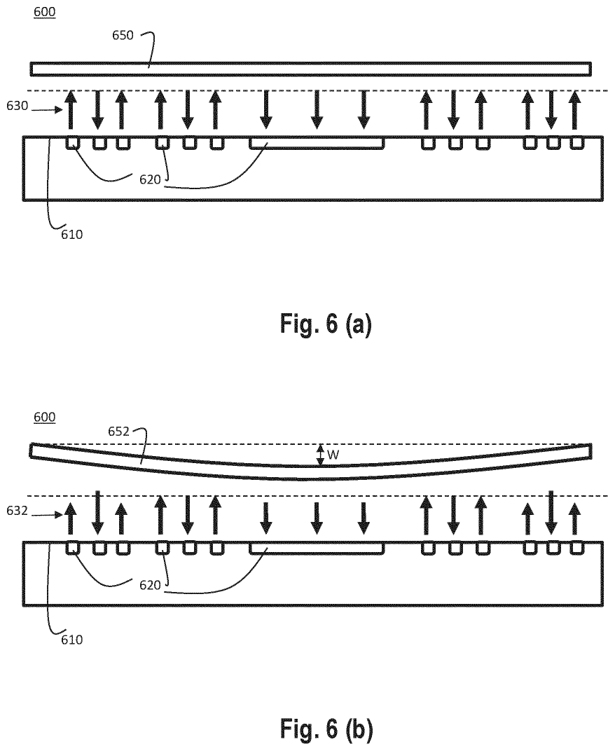

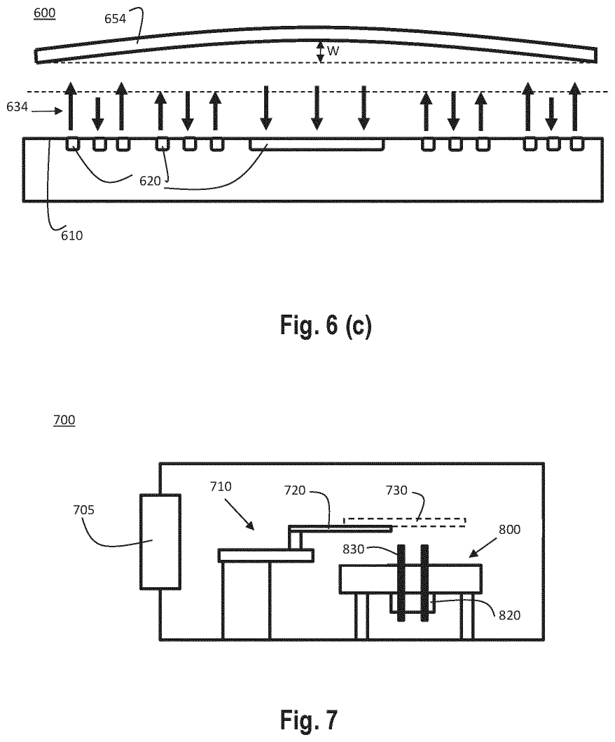

By controlling the spatial pressure distribution, e.g. the applied amplitudes of the gas pressures at the gas inlets and gas outlets, as will be illustrated in FIG. 6, deformed or warped substrates can be conditioned in an improved manner. A further advantage of this type of control is that during the process of clamping the substrate, the movement of the substrate is better defined and can be controlled, i.e. modified, to a certain degree. As such, this helps in avoiding a collision between the substrate and the top surface and also helps in controlling the actual shape of the substrate during the clamping process. With respect to the latter, it can be pointed out that control of the spatial pressure distribution as presented by the present invention enables to locally bring the substrate into a desired shape such that the remainder of the substrate can be clamped more easily. The type of control of the spatial pressure distribution provided by the present invention may also enable to better control the gas consumption during the clamping process and enables a better control of the local deflection or deformation of the substrate, i.e. it allows to ensure that the local deflection of the substrate does not become too large.

FIG. 6 schematically shows a thermal conditioning unit with a substrate and a representation of the applied spatial pressure distribution for three different situations.

FIG. 6 (a) schematically shows a cross-sectional view of a thermal conditioning unit 600, the thermal conditioning unit having a plurality of gas inlets and gas outlets provided in the top surface 610, e.g. grouped along a plurality of grooves and recesses 620 which can be provided with a controlled gas supply or gas extraction. Note that the internal ducts or channels are not shown. FIG. 6 (a) further schematically shows a substrate 650 that is to be conditioned by the thermal conditioning unit 600. In the arrangement as shown, the substrate 650 is considered to be substantially flat, i.e. substantially free from out-of-plane deformations. Arrows 630 schematically illustrate the spatial pressure distribution to be applied to hold the substantially flat substrate 650 at a desired fly-height above the top surface 610 of the thermal conditioning unit.

FIG. 6 (b) schematically shows a cross-sectional view of the thermal conditioning unit 600 as shown in FIG. 6 (a). FIG. 6 (b) further schematically shows a substrate 652 that is to be conditioned by the thermal conditioning unit 600. In the arrangement as shown, the substrate 652 is a warped substrate which shape can be described as bowl-shaped. The substrate thus has an out-of-plane deformation; or phrased differently, the substrate is not flat. When such a substrate 652 would be held by the thermal conditioning unit 600, using a spatial pressure distribution 630 shown in FIG. 6 (a), the following problems could arise:
The fly-height, i.e. the distance at which the substrate 652 is held above the top-surface of the thermal conditioning unit, may be outside a desired range and/or may vary across the top surface. As such, the thermal conditioning process may not be optimal, e.g. resulting in a non-uniform temperature distribution of the substrate 652. A non-uniform temperature distribution of the substrate may result in an inaccurate patterning process, e.g. causing an overlay error.
The substrate, in particular a central portion of the substrate 652, may come in contact with the thermal conditioning unit, causing damage to the substrate 652, or the top surface 610 or both.

In order to enable an improved thermal conditioning of warped substrates such as substrate 652, the present invention proposes to apply an adjusted or modified spatial pressure distribution. In particular, in order to suitably condition a bowl-shaped substrate such as substrate 652, the adjusted spatial pressure pattern as applied may e.g. be represented by the arrows 632. Compared to the spatial pressure pattern 630, the spatial pressure pattern 632 applies a reduced repelling force at the outer regions of the substrate 652 and a reduced attractive force at a central region of the substrate 652. Note that the dotted line 640 indicates a reference to the nominal forces applied for a flat substrate such as substrate 650.

As will be understood by the skilled person, the most appropriate pressure distribution for a particular substrate can e.g. be determined empirically or based on simulations, e.g. finite element simulations. Based on such experiments or simulations, one can e.g. determine a suitable spatial pressure distribution for a given value of the warpage of the substrate. In an embodiment, the warpage of the substrate, e.g. substrate 652, can be characterized by the value of the distance W as indicated in FIG. 6 (b). Note that, as mentioned above, the various pressures at the gas inlets and gas outlets as applied may vary during the clamping process. As such, in an embodiment, the most appropriate spatial pressure distribution as applied by the present invention may by a dynamic spatial pressure distribution, i.e. a time-varying pressure distribution, at least during the clamping process. As an example, the most appropriate pressure distribution may also include a sequence indicating the timing and in which order the various pressure valves need to be operated.

In an embodiment of the present invention, the control device, e.g. control device 470 can be equipped to stored, in a memory unit, desired set points for the pressure values of the thermal conditioning unit to realize the desired spatial pressure distribution, for a given value W. In general, the control device of the thermal conditioning unit according to the invention can be configured to determine a control set point for the plurality of pressure valves based on the substrate shape data, e.g. substrate warpage data. As will be clear from the above, such set points for the pressure valves may be time dependent, i.e. formulated as a function of time.

In an embodiment, the control device may also be configured to determine a control sequence for operating the plurality of pressure valves, based on the substrate shape data, e.g. the warpage data. Such a control sequence can e.g. represent an order in which the pressure valves are operated to establish the desired spatial pressure distribution.

In case of a bowl-shaped substrate such as substrate 652, it may be preferred to clamp a central portion of the substrate first, e.g. by extracting gas from the central gas inlet of the thermal conditioning unit 600 and then progressing towards a neighboring or surrounding areas. In general, the modified spatial pressure distribution as applied in the present invention may be, at least during the clamping process, a time dependent or time varying spatial pressure distribution to accommodate for the clamping or suspending of warped or deformed substrates. As such, the timing of activating the different gas inlets and gas outlets may in general, according to the invention, vary depending on the type of substrate that needs to be conditioned, in particular depending on the substrate shape data.

FIG. 6 (c) schematically shows a cross-sectional view of the thermal conditioning unit 600 as shown in FIGS. 6 (a) and 6 (b) and further schematically shows yet another substrate 654 that is to be conditioned by the thermal conditioning unit 600. In the arrangement as shown, the substrate 654 is a warped substrate which shape can be described as umbrella-shaped. The substrate thus has an out-of-plane deformation; or phrased differently, the substrate is not flat. When such a substrate 654 would be held by the thermal conditioning unit 600, using a spatial pressure distribution 630 shown in FIG. 6 (a), the following problems could arise:
The fly-height, i.e. the distance at which the substrate 654 is held above the top-surface of the thermal conditioning unit, may be outside a desired range and/or may vary across the top surface. As such, the thermal conditioning process may not be optimal, e.g. resulting in a non-uniform temperature distribution of the substrate 654. A non-uniform temperature distribution of the substrate may result in an inaccurate patterning process, e.g. causing an overlay error.
The substrate, in particular the outer portions of the substrate 654, may come in contact with the thermal conditioning unit, causing damage to the substrate 654, or the top surface 610 or both.

In order to enable an improved thermal conditioning of warped substrates such as substrate 654, the present invention proposes to apply an adjusted or modified spatial pressure distribution. In particular, in order to suitably condition an umbrella-shaped substrate such as substrate 654, the adjusted spatial pressure pattern as applied may e.g. be represented by the arrows 634. Compared to the spatial pressure pattern 630, the spatial pressure pattern 634 applies an increased repelling force at the outer regions of the substrate 632 and an increased attractive force at a central region of the substrate 654. Note that the dotted line 640 indicates a reference to the nominal forces applied for a flat substrate such as substrate 650.

As will be understood by the skilled person, in a similar manner as discussed with reference to FIG. 6 (b), the most appropriate pressure distribution for a particular substrate can e.g. be determined empirically or based on simulations, e.g. finite element simulations. Based on such experiments or simulations, one can e.g. determine a suitable spatial pressure distribution for a given value of the warpage of the substrate, the warpage e.g. being indicated by the value of the distance W as indicated in FIG. 6 (c).

Comparing the adjusted or modified spatial pressure distributions 632 and 634 with the deformations of the substrates 652 and 654, one can understand that the adjusted spatial pressure distributions as applied will cause a force or distributed force to act on the substrate which at least partially counteracts the deformation of the to-be-conditioned substrate. As a result, the to-be-conditioned substrate will be held by the thermal conditioning unit in a more flattened state, improving the thermal conditioning process. As such, the fly-height of the substrate can more easily be maintained within a desired range. As an example, the fly-height of the substrate above the top surface of the thermal conditioning unit should preferably within a range from 10 μm to 20 μm.

In the thermal conditioning unit according to the present invention, the thermal conditioning of the substrate primarily occurs by heat transfer via conduction in the substrate and heat transfer via convection to and from the supplied gas. The controlled fly-height ensures that a desired heat transfer occurs across the entire substrate. A non-uniform fly-height would disturb the desired heat transfer process and could thus result in hot spots or cold spots on the substrate.

During the thermal conditioning process performed by the thermal conditioning unit according to the invention, the substrate may be caused to rotate, to further improve the thermal conditioning. In such embodiment, the substrate may e.g. be rotated at a speed of approx. 4 rad/s for different intervals in time or continuously during the thermal conditioning process.

FIGS. 6 (b) and 6 (c) schematically illustrate that by applying a modified spatial pressure distribution in accordance with the present invention, warped or deformed substrates may advantageously be clamped or suspended on a thermal conditioning unit according the present invention. The application of the present invention, i.e. the application of the modified spatial pressure profile, may further include one or more of the following control aspects:
The application of different pressure setpoints over time, i.e. time-dependent pressure setpoints may e.g. be useful to boost a gas flow at the start instance, or to reduce the gas flow, or stabilize a gas outlet, e.g. a supply of CDA, before a gas inlet is switched, or perform a step-wise inside-out clamping sequence for bowls to ensure better controlled roll-off and limit a required control range.
The application of a feedforward control, optionally combined with a pressure feedback control,
The generation of a local pneumatic torque by applying different pressures at certain instants at particular gas inlets and gas outlets. As an example, such a local pneumatic torque can be realized, with reference to FIG. 5, by connecting gas outlets 540.1 and 540.3 to different gas supplies. When a pressure difference is applied between said outlets, a local torque is exerted on the substrate. As an alternative to connecting the gas outlets 540.1 and 540.2 to different gas supplies, a restriction may be applied in one of the channels or ducts connecting the gas outlets to the gas supply. By doing, a temporarily local pressure torque will be generated because the pressure build up will occur at a different pace in both channels.
Non-rotationally symmetric pressure differences can be implemented in the thermal conditioning unit according to the present invention, e.g. to perform non-uniform conditioning. Such a non-uniform conditioning may e.g. be applied to compensate for asymmetric effects in any part of the lithographic apparatus processing the substrate or in the substrate, e.g. substrates with larger orthotropic properties or saddle-shapes.

In accordance with an aspect of the present invention, there is further provided a substrate handling device that comprises a thermal conditioning unit according to the invention.

Such a substrate handling device is schematically shown in FIG. 7.

FIG. 7 schematically shows a substrate handling device 700, also referred to as a substrate handler, comprising a thermal conditioning unit 800 according to the present invention. In the embodiment as shown, the substrate handling device comprises an inlet port 705 for receiving a substrate and a handling robot 710 configured to position the substrate onto the thermal conditioning unit 800. In an embodiment, such a handling robot 710 can e.g. comprise a gripper 720 for holding the substrate, indicated by the dotted line 730, and can be configured to transport the substrate to a position above the top surface 810 of the thermal conditioning unit 800. In the embodiment as shown, the thermal conditioning unit 800 further comprises a loading mechanism 820 comprising a plurality of loading pins 830. Said loading pins can be moved, by the loading mechanism 820, to an upward position to support the substrate indicated by the dotted line 730, thereby arranging a take-over of the substrate from the gripper 720 to the loading pins 830. Once the substrate is held by the loading pins, the gripper 720 can retract and the substrate can be lowered until it is held suspended above the top surface 810 by means of the spatial pressure distribution provided by the thermal conditioning unit 800. Note that, an alternative to the use of loading pins 830, a single loading support for temporarily holding the substrate may be applied as well. Such a loading support may e.g. be located at a central position of the conditioning unit, e.g. at the center of the support structure, e.g. structure 450 shown in FIG. 4, and may comprising a clamping mechanism such as a vacuum clamp or electrostatic clamp to hold the substrate. When the substrate is held by the clamp and the gripper 720 is retracted, the single loading support can be lowered. Alternatively, instead of lowering the loading support or the loading pins 830, one can arrange the support structure of the thermal conditioning unit to be moved upwards.

In the embodiment as shown, the handling robot 710 and the thermal conditioning unit 800 are arranged in an enclosure or housing 750.

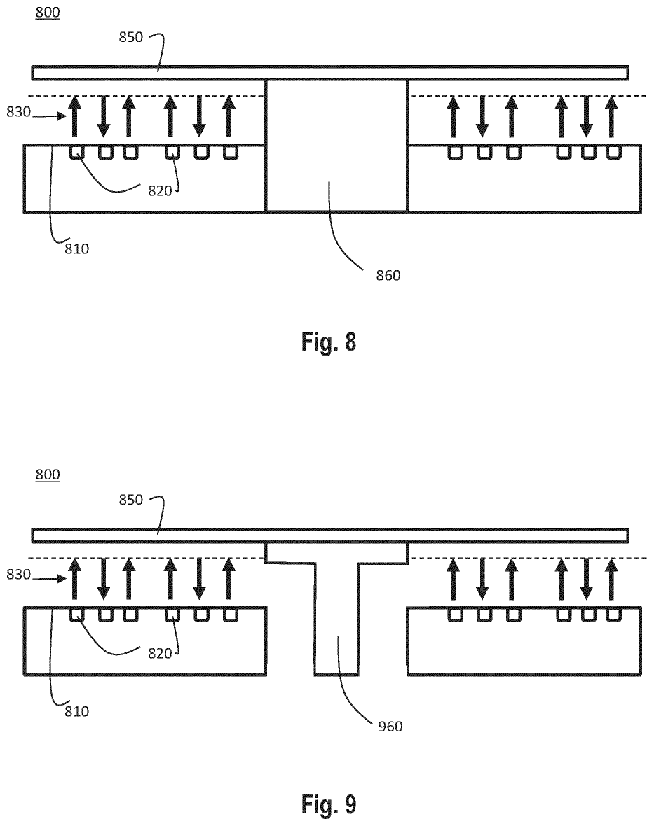

The aforementioned embodiments of the thermal conditioning unit are illustrated and described as having a central recess e.g. 540.7, 620 associated with gas inlet 520.1. In an alternative embodiment of the invention, the thermal conditioning unit may be provided with a support chuck. FIG. 8 schematically shows a cross-sectional view of a thermal conditioning unit 800, the thermal conditioning unit having a plurality of gas inlets and gas outlets provided in the top surface 810, e.g. grouped along a plurality of grooves and recesses 820 which can be provided with a controlled gas supply or gas extraction. Note that the internal ducts or channels are not shown. FIG. 8 schematically shows in cross-section a substrate 850 that has been conditioned by the thermal conditioning unit 800. In the arrangement as shown, the substrate 850 is illustrated as substantially flat, as conditioning has been carried out. The skilled person will understand that this is not a limitation of the embodiment—the thermal conditioning on this substrate may be continuous, or the substrate may be inherently substantially free of out-of-plane deformations. Arrows 830 schematically illustrate an example spatial pressure distribution applied to condition substrate 850 at a desired fly-height above the top surface 810 of the thermal conditioning unit. The thermal conditioning unit 800 further comprises a support chuck 860, configured to physically support the substrate 850. Support chuck 860 may comprise a clamping mechanism such as a vacuum clamp or electrostatic clamp to hold the substrate 850. Note that this is not shown in FIG. 8. Support chuck 860 has at least one degree of freedom. In the embodiment of FIG. 8, support chuck 860 is moveable at least in the z-direction, so as to raise and/or lower substrate 850. Support chuck 860 may also have movement in Rz, to enable rotation of substrate 850 around the z-axis. In the embodiment shown in FIG. 8, the support chuck 860 contacts the lower surface of substrate 850 after the substrate has been flattened in a floating matter by the spatial pressure distribution generated by the thermal conditioning unit. Advantageously, local roll-off induced stress when clamping is reduced, leading to improved accuracy in subsequent substrate processing steps.

In an alternative embodiment, shown in FIG. 9, the support chuck 960 may be shaped and configured to enable movement in up to six degrees of freedom (i.e. lateral and transverse movement, as well as rotational movement around three axes: x, y, z, Rx, Ry, Rz). The features shown in FIG. 9 are the same as those described for FIG. 8. The T-shaped cross-section of support chuck 960 shown in FIG. 9 allows for additional lateral displacement of a supported (clamped) substrate 850. Advantageously, the control of the substrate in more than one degree of freedom allows for more accurate and efficient thermal conditioning and/or clamping. The use and advantages of the embodiment of FIG. 8 also apply to that of FIG. 9.

The skilled person will note that although the support chuck of FIGS. 8 and 9 is shown at the center of the thermal conditioning unit, any other appropriate location may be used. Furthermore, a plurality of support chucks may be used, for example instead of providing a single central support chuck, a plurality of support chucks may be provided at or towards an edge of the thermal conditioning unit.

In accordance with an aspect of the present invention, there is provided a substrate support comprising a thermal conditioning unit in accordance with the invention. Said substrate support may for example be a wafer table, and may be as described and illustrated with reference to FIG. 1.

According to an aspect of the present invention, there is provided a lithographic apparatus comprising a thermal conditioning unit according to the present invention or a substrate handling device according to the invention. In the latter case, in an embodiment, a handling robot and thermal conditioning unit of the substrate handler can be arranged in an enclosure or housing of the lithographic apparatus. The thermal conditioning unit or substrate handling device according to the invention may advantageously be applied in a lithographic apparatus, in order to improve the thermal conditioning of substrates, prior to the substrates being subjected to a patterning process. The improved thermal conditioning of the substrates may result in a more accurate patterning process, resulting in an improved yield of the lithographic apparatus.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM);

magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set out as in the following numbered clauses:

1. A thermal conditioning unit to thermally condition a substrate comprising:
a top surface;
a plurality of gas inlets and gas outlets provided in the top surface;
a plurality of pressure valves connected to the plurality of gas inlets and gas outlets, wherein each of the plurality of pressure valves is configured to, during use, be connected to a pressure supply to generate a spatial pressure distribution across the top surface of the thermal conditioning unit,
a control device configured to control the plurality of pressure valves to generate, during use, the spatial pressure distribution,
wherein the control device is configured to receive substrate shape data representing a shape of the substrate to be conditioned, and wherein the control device is configured to control the plurality of pressure valves to adapt the spatial pressure distribution based on the substrate shape data.

2. The thermal conditioning unit according to clause 1, wherein the spatial pressure distribution provides a vacuum preloaded gas bearing for the substrate.

3. The thermal conditioning unit according to any of the preceding clauses, wherein the spatial pressure distribution comprises a plurality of concentric ring-shaped pressure areas.

4. The thermal conditioning unit according to any of the preceding clauses, wherein the plurality of gas outlets are arranged along one or more concentric circles.

5. The thermal conditioning unit according to any of the preceding clauses, wherein the plurality of gas inlets are arranged along one or more concentric circles.

6. The thermal conditioning unit according to any of the preceding clauses, wherein the top surface comprises a plurality of grooves, each groove comprising one or more gas inlets or one or more gas outlets.

7. The thermal conditioning unit according to clause 6, wherein the plurality of grooves are arc or circular shaped.

8. The thermal conditioning unit according to any of the preceding clauses, wherein the substrate shape data comprises warpage data.

9. The thermal conditioning unit according to clause 8, wherein the control device is configured to determine a control sequence and/or control set point for the plurality of pressure valves based on the warpage data.

10. The thermal conditioning unit according to clause 9, wherein the control sequence represents an order in which the pressure valves are operated to establish the spatial pressure distribution.

11. The thermal conditioning unit according to any preceding clause, further comprising a support chuck having at least one degree of freedom.

12. A method of using a thermal conditioning unit according to any of the preceding clauses, comprising the steps of:
connecting each of the plurality of pressure valves to a pressure supply,
receiving at the control device substrate shape data representing a shape of the substrate to be conditioned,
controlling the supply of an over-pressure, under-pressure, and/or ambient pressure to each of the plurality of pressure valves to generate a spatial pressure distribution across the top surface of the thermal conditioning unit, wherein the spatial pressure distribution is based on the substrate shape data.

13. The method of using a thermal conditioning unit according to clause 12, further comprising the steps of:
conditioning the substrate with the generated spatial pressure distribution, and
clamping the conditioned substrate.

14. A substrate handling device comprising a thermal conditioning unit according to any of clauses 1-11.

15. The substrate handling device according to clause 14, further comprising an inlet port for receiving a substrate and a handling robot configured to position the substrate onto the thermal conditioning unit.

16. A substrate support comprising a thermal conditioning unit according to any of clauses 1 to 11.

17. A method of using a substrate support according to clause 16, comprising the steps of:
connecting each of the plurality of pressure valves to a pressure supply,
receiving at the control device substrate shape data representing a shape of the substrate to be conditioned,
controlling the supply of an over-pressure, under-pressure, and/or ambient pressure to each of the plurality of pressure valves to generate a spatial pressure distribution across the top surface of the thermal conditioning unit, wherein the spatial pressure distribution is based on the substrate shape data.

18. The method of using a substrate support according to clause 17, further comprising the steps of:
conditioning the substrate with the generated spatial pressure distribution, and
clamping the conditioned substrate.

19. A lithographic apparatus comprising a thermal conditioning unit according to any of the clauses 1 to 11, a substrate handling device according to any of the clauses 14 to 15 or a substrate support according to clause 16.

1. A thermal conditioning unit to contactlessly thermally condition a substrate, the thermal conditioning unit comprising:
a top surface;
a plurality of gas inlets and gas outlets provided in the top surface;
a plurality of pressure valves connected to the plurality of gas inlets and gas outlets, wherein each of the plurality of pressure valves is configured to, during use, be connected to a pressure supply to generate a spatial pressure distribution across the top surface of the thermal conditioning unit; and
a control device configured to control the plurality of pressure valves to generate, during use, the spatial pressure distribution,
wherein the control device is configured to receive substrate shape data representing a shape of the substrate to be conditioned, wherein the control device is configured to control the plurality of pressure valves to adapt the spatial pressure distribution based on the substrate shape data and wherein the spatial pressure distribution provides a vacuum preloaded gas bearing to support the substrate.

2. (canceled)

3. The thermal conditioning unit according to claim 1, wherein the spatial pressure distribution comprises a plurality of concentric ring-shaped pressure areas.

4. The thermal conditioning unit according to claim 1, wherein the plurality of gas outlets are arranged along one or more concentric circles.

5. The thermal conditioning unit according to claim 1, wherein the plurality of gas inlets are arranged along one or more concentric circles.

6. The thermal conditioning unit according to claim 1, wherein the top surface comprises a plurality of grooves, each groove comprising one or more gas inlets or one or more gas outlets.

7. The thermal conditioning unit according to claim 6, wherein the plurality of grooves are arc or circular shaped.

8. The thermal conditioning unit according to claim 1, wherein the substrate shape data comprises warpage data.

9. The thermal conditioning unit according to claim 8, wherein the control device is configured to determine a control sequence and/or control set point for the plurality of pressure valves based on the warpage data.

10. The thermal conditioning unit according to claim 9, wherein the control device is configured to determine the control sequence and wherein the control sequence represents an order in which the pressure valves are operated to establish the spatial pressure distribution.

11. The thermal conditioning unit according to claim 1, further comprising a support chuck having at least one degree of freedom.

12. A method of using a thermal conditioning unit according to claim 1, the method comprising:
connecting each of the plurality of pressure valves to a pressure supply,
receiving, at the control device, substrate shape data representing a shape of the substrate to be conditioned, and
controlling the supply of an over-pressure, under-pressure, and/or ambient pressure to each of the plurality of pressure valves to generate a spatial pressure distribution across the top surface of the thermal conditioning unit, wherein the spatial pressure distribution is based on the substrate shape data.

13. The method according to claim 12, further comprising:
conditioning the substrate with the generated spatial pressure distribution, and
clamping the conditioned substrate.

14. A substrate handling device comprising the thermal conditioning unit according to claim 1.

15. The substrate handling device according to claim 14, further comprising an inlet port configured to receive a substrate and a handling robot configured to position the substrate onto the thermal conditioning unit.

16. A substrate support comprising a thermal conditioning unit according to claim 1.

17. A method of using the substrate support according to claim 16, the method comprising:
connecting each of the plurality of pressure valves to a pressure supply,
receiving at the control device substrate shape data representing a shape of the substrate to be conditioned,
controlling the supply of an over-pressure, under-pressure, and/or ambient pressure to each of the plurality of pressure valves to generate a spatial pressure distribution across the top surface of the thermal conditioning unit, wherein the spatial pressure distribution is based on the substrate shape data.

18. The method according to claim 17, further comprising:
conditioning the substrate with the generated spatial pressure distribution, and
clamping the conditioned substrate.

19. A lithographic apparatus comprising the thermal conditioning unit according to claim 1.

20. The method according to claim 12, wherein the spatial pressure distribution comprises a plurality of concentric ring-shaped pressure areas.

21. The method according to claim 17, wherein the spatial pressure distribution comprises a plurality of concentric ring-shaped pressure areas.
